(19) United States
(12) Patent Application Publication
(10) Pub. No.: US 2017/0194405 A1
(43) Pub. Date: Jul. 6, 2017

(54) ORGANIC LIGHT EMITTING DISPLAY AND METHOD OF MANUFACTURING THE SAME

(71) Applicants: Shenzhen China Star Optoelectronics Technology Co., Ltd., Guangdong (CN); Wuhan China Star Optoelectronics Technology Co., Ltd., Wuhan, Hubei (CN)

(72) Inventor: Fu-hsiung TANG, Guangdong (CN)

(21) Appl. No.: 14/901,421

(22) PCT Filed: Sep. 16, 2015
(86) PCT No.: PCT/CN2015/089749

§ 371 Date: Dec. 28, 2015

(30) Foreign Application Priority Data
Aug. 13, 2015 (CN) 201510494172.3

(51) Int. Cl. H01L 27/32; H01L 51/56

(52) U.S. Cl. CPC H01L 27/3262; H01L 51/56; H01L 27/3258; H01L 2251/558; H01L 2227/323

(57) ABSTRACT

The present disclosure discloses an organic light emitting display and a method of manufacturing the same. The manufacturing method includes: forming a gate electrode of a first thin film transistor (TFT) on a substrate; forming a first insulating combination layer, and a source electrode and a drain electrode of the first TFT, a source electrode and a drain electrode of a second TFT and a first storage electrode of a storage capacitor located on the first insulating combination layer continuously; forming a third insulating layer on the first insulating combination layer, the source electrode and the drain electrode and the first storage electrode; forming the gate electrode of the second TFT and a second storage electrode of the storage capacitor on the third insulation layer; forming a second insulating combination layer on the third insulating layer; and forming a through hole in the second insulation combination layer.

### BACKGROUND OF THE INVENTION

1. Field of the Invention

The present disclosure belongs to a technical field of a display, in particular, relates to an organic light emitting display and a method of manufacturing the same.

2. Description of the Prior Art

The organic light emitting display has self-luminous characteristics and excellent display characteristics in comparison with a liquid crystal display (LCD), for example, a view angle, a contrast, a response speed, power consumption, etc.

The organic light emitting display can include an organic light emitting diode (OLED) having an anode, an organic thin film and a cathode. The organic light emitting display can be classified into a passive-matrix organic light emitting display or an active-matrix organic light emitting display. In the passive-matrix organic light emitting display, OLEDs are connected between scan lines and data lines to form pixels. However, in the active-matrix organic light emitting display, each of the pixels is controlled by a thin film transistor (TFT) used as a switch.

Usually, the TFT used in the active-matrix organic light emitting display can include an active layer for providing a channel region, a source region and a drain region and a gate electrode formed on the channel region, and the gate electrode can be electrically insulated from the active layer through a gate insulating layer. The active layer of the TFT usually can be formed of a semiconductor layer such as an amorphous silicon layer or a polycrystalline silicon layer.

Nevertheless, when the active layer is formed of the amorphous silicon, mobility may be very low. Thus, it may be very difficult to implement driving circuit at a high speed.

The mobility of the TFT having the polycrystalline silicon active layer increases in comparison with the TFT having the amorphous silicon active layer, but at least two TFTs and a storage capacitor are needed. One of the two TFTs runs as a Switch device, and the other one runs as a Driving device.

The TFT running as the Switch device needs to have a rapid turning ON or OFF characteristic, that is, an Id-Vg characteristic curve is more steep, which corresponds to a smaller sub-threshold swing; while the TFT running as the Driving device needs to have a larger sub-threshold swing, that is, an Id-Vg curve is more gentle, so as to provide a gentle output current to make the OLED emit light regularly. However, in the existing manufacturing technology, the TFT manufactured by the adopted manufacturing method cannot satisfy the above requirements.

### SUMMARY OF THE INVENTION

Thus, the present disclosure discloses an organic light emitting display and a method of manufacturing the same, which can resolve the problem existing in the above prior art.

According to an aspect of the present disclosure, it is provided a method of manufacturing an organic light emitting display, including forming a gate electrode of a first thin film transistor (TFT) on a substrate; forming a first insulating combination layer to cover the gate electrode of the first TFT and a source electrode, a drain electrode of the first TFT, the source electrode and the drain electrode of a second TFT and a first storage electrode of a storage capacitor located on the first insulating combination layer continuously; forming a third insulating layer on the first insulating combination layer to cover the source electrode and the drain electrode of the first TFT, the source electrode and the drain electrode of the second TFT and the first storage electrode of the storage capacitor; forming the gate electrode of the second TFT and a second storage electrode of the storage capacitor on the third insulating layer; forming a second insulating combination layer to cover the gate electrode of the second TFT and the second storage electrode of the storage capacitor on the third insulating layer; forming a through hole in the second insulating combination layer to expose the source electrode and the drain electrode of the first TFT and the source electrode and the drain electrode of the second TFT.

Further, the second insulating combination layer formed by a fourth insulating layer and a fifth insulating layer is formed on the second insulating layer.

Further, the first insulating combination layer composed by the first insulating layer and the second insulating layer, and the source electrode and the drain electrode of the first TFT, the source electrode and the drain electrode of the second TFT and the first storage electrode of the storage capacitor directly located on the second insulating layer, are formed on the substrate.

Further, a thickness of the third insulating layer is smaller than a thickness of the first insulating combination layer.

Further, the fourth insulating layer is made of silicon oxide; and the fifth insulating layer is made of silicon nitride.

Further, the first insulating layer is made of the silicon oxide; and the second insulating layer is made of the silicon nitride.

Further, the third insulating layer is made of the silicon oxide.

Further, the source electrode and the drain electrode of the first TFT and the source electrode and the drain electrode of the second TFT are all made of p-type doped polycrystalline silicon, the first storage electrode of the storage capacitor is made of p-type doped polycrystalline silicon, and the second storage electrode of the storage capacitor is made of polycrystalline silicon.

Further, the manufacturing method further includes: forming an electrode contacting the source electrode of the first TFT, an electrode contacting the drain electrode of the first TFT, an electrode contacting the source electrode of the second TFT and an electrode contacting the drain electrode of the second TFT on the second insulating combination layer.

According to another aspect of the present disclosure, it is provided an organic light emitting display manufactured by using the above manufacturing method.

Advantageous effects of the present disclosure are as follows: in the present disclosure, the first TFT having a bottom gate structure and the second TFT having a top gate structure can be prepared simultaneously in the same process, so that the second TFT running as the Switch device can be provided with the improved ON-OFF characteristics (for example, rapid turning ON or OFF characteristic, that is, the Id-Vg characteristic curve is more steep, which corresponds to the smaller sub-threshold swing) and the first TFT running as the Driving device can be provided with the larger sub-threshold swing, that is, the Id-Vg curve is more gentle, so as to provide the gentle output current to make the OLED emit light regularly.

### BRIEF DESCRIPTION OF THE DRAWINGS

These and/or other aspects, characteristics and advantages of the embodiments in the present disclosure will become apparent and more readily appreciated from the following description, taken in conjunction with the accompanying drawings in which:

FIGS. 1A and 1B show a plane view and a sectional view of an organic light emitting display according to an embodiment of the present disclosure, respectively;

FIG. 2 shows a circuit diagram of pixels according to an embodiment of the present disclosure; and

FIG. 3 shows a sectional view of a first TFT, a second TFT and a storage capacitor.

### DETAILED DESCRIPTION OF EXEMPLARY EMBODIMENTS

Embodiments of the present disclosure will be described in detail below by referring to the accompany drawings. However, the present disclosure can be implemented in numerous different forms, and the present disclosure should not be explained to be limited hereto. Instead, these embodiments are provided for explaining the principle and actual application of the present disclosure, so that those skilled in the art can understand various embodiments and amendments which are suitable for specific intended applications of the present disclosure. In the figures, in order to see the devices clearly, thicknesses of a layer and an area are exaggerated, and the same reference numerals in the whole description and figures can be used to denote the same elements. It will be also understood that, when a layer or element is referred to be disposed “on” another layer or substrate, it can be directly disposed on the another layer or substrate, or there may be an intermediate layer.

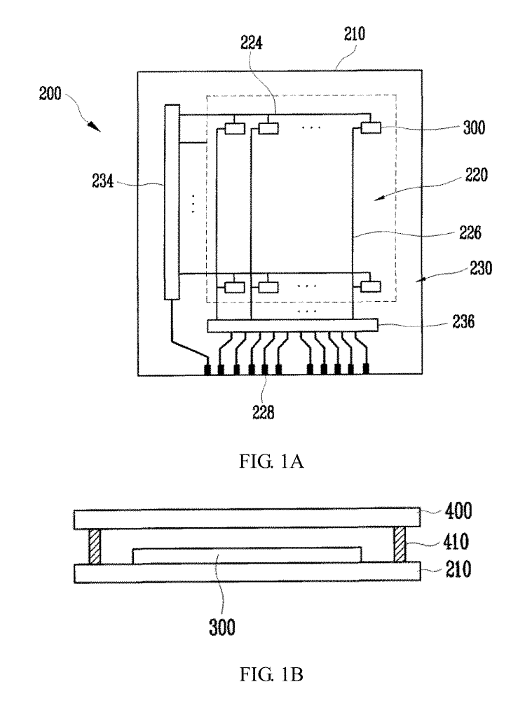

FIGS. 1A and 1B show a plane view and a sectional view of an organic light emitting display according to an embodiment of the present disclosure, respectively.

Referring to FIG. 1A, an organic light emitting display 200 according to an embodiment of the present disclosure includes a substrate 210, wherein the substrate 210 is divided into a pixel area 220 and a non-pixel area 230 surrounding the pixel area 220. For example, a plurality of pixels 300 arranged in a matrix pattern and connected to each other between scan lines 224 and data lines 226 can be formed in the pixel area 220 on the substrate 210. A scan driver 234 connected to the scan lines 224, and a data driver 236 for processing a data signal provided from the outside through pads 228 and providing the processed data signal to the data lines 226, and so on, can be formed in the non-pixel area 230 on the substrate 210. The data lines 226 and the scan lines can extend from the respective pixels 300, that is, extend from the pixel area 220 to the non-pixel area 230. Each of the respective pixels 300 can include a pixel circuit having a plurality of TFTs and at least one OLED connected to the pixel circuit.

Referring to FIG. 1B, a package substrate 400 for sealing the pixel area 220 can be disposed above the substrate 210, and the pixels 300 are formed therein as stated above. The package substrate 400 can be adhered to the substrate 210 through a sealing material 410. Thus, the plurality of pixels 300 can be sealed between the substrate 210 and the package substrate 400. Each of the plurality of pixels 300 formed on the substrate 210 can include a plurality of TFTs. Each of the plurality of TFTs can have different characteristics according to operations executed thereby. For example, a pixel 300 can include a TFT running as a Switch device and a TFT running as a Driving device.

According to an embodiment of the present disclosure, different TFTs in the organic light emitting display 200, for example, two TFTs in the pixel 300, can include a TFT having a bottom gate structure and a TFT having a top gate structure formed in the same process, so that the TFTs having different characteristics can be realized in a single process. In other words, on the contrary to a conventional organic light emitting display, for example, a display having TFTs that have the same structures and are used for executing different operations and TFTs of which characteristics do not have any substantive differences, the TFT according to the embodiment of the present disclosure can have different structures formed in the single process, so as to facilitate improving different characteristics of the different TFTs. For example, since the TFTs according to the embodiment of the present disclosure have different structures, in the single process the TFT running as the Switch device can be provided with the improved ON-OFF characteristics (for example, rapid turning ON or OFF characteristic, that is, the Id-Vg characteristic curve is more steep, which corresponds to the smaller sub-threshold swing) and the TFT running as the Driving device can be provided with the larger sub-threshold swing, that is, the Id-Vg curve is more gentle, so as to provide the gentle output current to make the OLED emit light regularly.

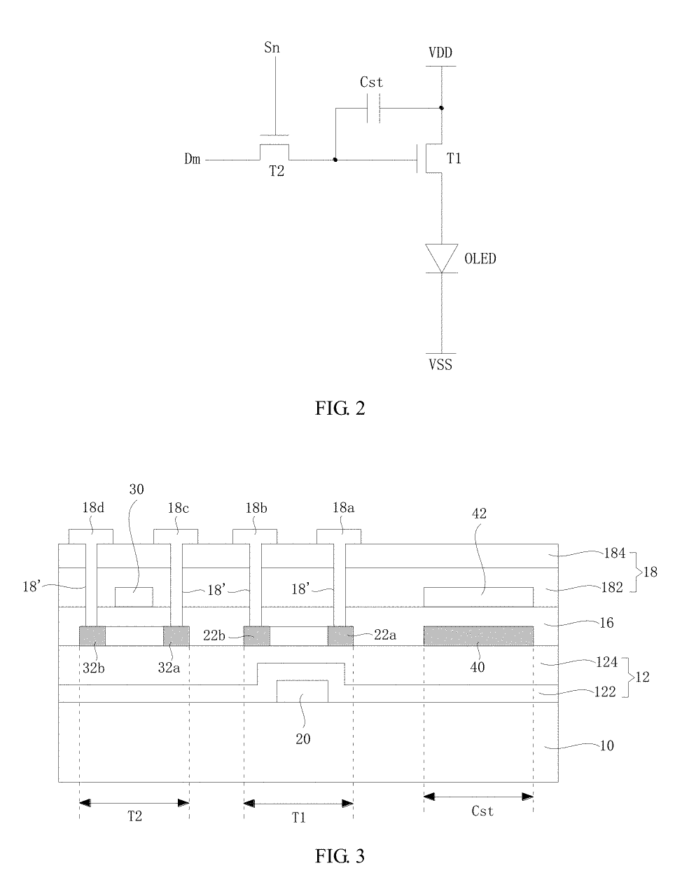

FIG. 2 shows a circuit diagram of pixels 300 according to an embodiment of the present disclosure. Nevertheless, it needs to be explained that, the pixel circuit in FIG. 2 is only an exemplary embodiment, and other pixel circuits used for the organic light emitting display 200 are also included in the scope of the present inventive concept.

Referring to FIG. 2, the pixel circuits of the pixels 300 can include a first TFT T1 as a driving TFT, a second TFT T2 as a switch TFT and a storage capacitor Cst. The first TFT T1 and the second TFT T2 can be lower temperature polycrystalline silicon (LTPS) TFTs.

In specific, according to the embodiment of the present disclosure, the first TFT T1 running as the Switch device can be implemented by the bottom gate structure, and the second TFT T2 running as the Driving device can be implemented by the top gate structure. Nevertheless, it should be noted that, although the first TFT T1 and the second TFT T2 in FIG. 2 are shown as p-type LTPS TFTs, other types of LTPS TFTs are also included in the scope of the present inventive concept.

Each of the first TFT T1 and the second TFT T2 can include a source electrode, a drain electrode and a gate electrode. The storage capacitor Cst can include a first storage electrode and a second storage electrode.

Further referring to FIG. 2, in the first TFT T1, the drain electrode can be connected to an anode of the OLED, and the source electrode can be connected to a first power source VDD. The gate electrode can be connected to a first node N.

In the second TFT T2, the source electrode can be connected to a data line Dm, the drain electrode can be connected to the first node N, and the gate electrode can be connected to a scan line Sn. Thus, a data signal selectively flowing through the data line Dm can be selectively transmitted to the first node N according to a scan signal transmitted by the scan line Sn.

In the storage capacitor Cst, the first storage electrode can be connected to the first power source VDD, and the second storage electrode can be connected to the first Node N.

The first TFT T1 and the second TFT T2 can be prepared in the same process, for example, simultaneously. Therefore, since the first TFT T1 and the second TFT T2 can have the bottom gate structure and the top gate structure, respectively, the TFTs having different characteristic can be realized in a single process without adding a mask process.

FIG. 3 shows a sectional view of a first TFT, a second TFT and a storage capacitor.

Referring to FIG. 3, a gate electrode 20 of the first TFT T1 can be formed on a substrate (e.g., a glass substrate) 10.

Next, a first insulating combination layer 12 to cover the gate electrode 20 and a source electrode 22a and a drain electrode 22b of the first TFT T1, a source electrode 32a and a drain electrode 32b of the second TFT T2 and a first storage electrode 40 of the storage capacitor Cst located on the first insulating combination layer 12 continuously. The source electrode 22a and the drain electrode 22b and the source electrode 32a and the drain electrode 32b, and the first storage electrode 40 can be separated from each other. The source electrode 22a and the drain electrode 22b, the source electrode 32a and the drain electrode 32b and the first storage electrode 40 can be formed on a substantially same level, that is, the source electrode 22a and the drain electrode 22b, the source electrode 32a and the drain electrode 32b and the first storage electrode 40 can be formed on a first insulating combination layer 12 simultaneously. For example, the first storage electrode 40 connects in contact with the first power source VDD.

The first insulating combination layer 12 can be constituted by a first insulating layer 122 and a second insulating layer 124, wherein the first insulating layer 122 is made of silicon oxide (SiO₂); and the second insulating layer 124 is made of silicon nitride (SiNₓ). The source electrode 22a and the drain electrode 22b of the first TFT T1, the source electrode 32a and the drain electrode 32b of the second TFT T2 and the first storage electrode 40 of the storage capacitor Cst all can be made of p-type doped polycrystalline silicon.

Here, the second insulating layer 124 made of the SiNₓ can insulate effects of metal ions in the substrate 210 on the respective devices to be formed, that is, the source electrode 22a and the drain electrode 22b of the first TFT T1, the source electrode 32a and the drain electrode 32b of the second TFT T2 and the first storage electrode 40 of the storage capacitor Cst can be directly formed on the second insulating layer 124.

Next, a third insulating layer 16 to cover the source electrode 22a and the drain electrode 22b, the source electrode 32a and the drain electrode 32b and the first storage electrode 40 is formed on the first insulating combination layer 12. Here, a thickness of the third insulating layer 16 is smaller than the thickness of the first insulating combination layer 12. The third insulating layer 16 is also made of SiO₂.

Next, a gate electrode 30 of the second TFT T2 and a second storage electrode 42 of the storage capacitor Cst are formed on the third insulation layer 16. The gate electrode 30 and the second storage electrode 42 can be separated from each other. The gate electrode 30 and the second storage electrode 42 can be formed on a substantially same level, that is, the gate electrode 30 and the second storage electrode 42 can be formed on the third insulating layer 16. The second storage electrode 42 of the storage capacitor Cst can be made of polycrystalline silicon. For example, the second storage electrode 42 connects in contact with the first node N.

Next, a second insulating combination layer 18 formed by combining a fourth insulating layer 182 and a fifth insulating layer184 to cover the gate electrode 30 and the second storage electrode 42 is formed on the third insulating layer 16. The fourth insulating layer 182 is made of the SiO₂. The fifth insulating layer 184 is made of the SiNₓ.

Next, a through hole 18′ is formed in the second insulation combination layer 18′ to expose the source electrode 22a and the drain electrode 22b of the first TFT T1 and the source electrode 32a and the drain electrode 32b of the second TFT T2.

At last, an electrode 18a contacting the source electrode 22a of the first TFT T1, an electrode 18b contacting the drain electrode 22b of the first TFT T1, an electrode 18c contacting the source electrode 32a of the second TFT T2 and an electrode 18d contacting the drain electrode 32b of the second TFT T2 are formed on the second insulating combination layer 18.

The four electrodes 18a, 18b, 18c and 18d can be made of Ti/Al/Ti metals. For example, the electrode 18a is in contact with the first power source VDD shown in FIG. 2, the electrode 18b is in contact with the anode of the OLED shown in FIG. 2, the electrode 18c is in contact with the data line Dm shown in FIG. 2, and the electrode 18d is in contact with the first node N shown in FIG. 2.

In summary, in the embodiments according to the present disclosure, the first TFT T1 having the bottom gate structure and the second TFT T2 having the top gate structure can be prepared simultaneously in the same process, so that the second TFT T2 running as the Switch device can be provided with the improved ON-OFF characteristics (for example, rapid turning ON or OFF characteristic, that is, the Id-Vg characteristic curve is more steep, which corresponds to the smaller sub-threshold swing) and the first TFT T1 running as the Driving device can be provided with the larger sub-threshold swing, that is, the Id-Vg curve is more gentle, so as to provide the gentle output current to make the OLED emit light regularly.

Although the present disclosure is described with reference to the special embodiments, while those skilled in the art will understand: various changes in form and details may be made therein without departing from the spirit and scope of the invention as defined by the appended claims and its equivalents.

What is claimed is:

1. A method of manufacturing an organic light emitting display, comprising:
forming a gate electrode of a first thin film transistor (TFT) on a substrate;
forming a first insulating combination layer to cover the gate electrode of the first TFT and a source electrode and a drain electrode of the first TFT, a source electrode and a drain electrode of a second TFT and a first storage electrode of a storage capacitor located on the first insulating combination layer continuously;
forming a third insulating layer on the first insulating combination layer to cover the source electrode and the drain electrode of the first TFT, the source electrode and the drain electrode of the second TFT and the first storage electrode of the storage capacitor;
forming the gate electrode of the second TFT and a second storage electrode of the storage capacitor on the third insulating layer;
forming a second insulating combination layer to cover the gate electrode of the second TFT and the second storage electrode of the storage capacitor on the third insulating layer; and
forming a through hole in the second insulating combination layer, to expose the source electrode and the drain electrode of the first TFT and the source electrode and the drain electrode of the second TFT.

2. The manufacturing method of claim 1, wherein the second insulating combination layer composed by a fourth insulating layer and a fifth insulating layer is formed on the second insulating layer.

3. The manufacturing method of claim 1, wherein the first insulating combination layer composed by the first insulating layer and the second insulating layer, and the source electrode and the drain electrode of the first TFT, the source electrode and the drain electrode of the second TFT and the first storage electrode of the storage capacitor directly located on the second insulating layer, are formed on the substrate.

4. The manufacturing method of claim 1, wherein a thickness of the third insulating layer is smaller than a thickness of the first insulating combination layer.

5. The manufacturing method of claim 2, wherein the fourth insulating layer is made of silicon oxide (SiO₂); and the fifth insulating layer is made of silicon nitride (SiNₓ).

6. The manufacturing method of claim 2, wherein the first insulating layer is made of the SiO₂; and the second insulating layer is made of the SiNₓ.

7. The manufacturing method of claim 2, wherein the third insulating layer is made of the SiO₂.

8. The manufacturing method of claim 1, wherein the source electrode and the drain electrode of the first TFT and the source electrode and the drain electrode of the second TFT are all made of p-type doped polycrystalline silicon, the first storage electrode of the storage capacitor is made of the p-type doped polycrystalline silicon, and the second storage electrode of the storage capacitor is made of polycrystalline silicon.

9. The manufacturing method of claim 1, wherein the manufacturing method further comprises:
forming an electrode contacting the source electrode of the first TFT, an electrode contacting the drain electrode of the first TFT, an electrode contacting the source electrode of the second TFT and an electrode contacting the drain electrode of the second TFT on the second insulating combination layer.

10. An organic light emitting display manufactured by using the method of manufacturing an organic light emitting display of claim 1.
